(19) United States
(12) Patent Application Publication
(10) Pub. No.: US 2009/0226763 A1
(43) Pub. Date: Sep. 10, 2009

(54) Perpendicular magnetic recording medium, production process thereof, and magnetic recording and reproducing apparatus

(75) Inventor: Masahiro Oka, Yokohama-shi (JP)

Correspondence Address: SUGHRUE MION, PLLC, 2100 PENNSYLVANIA AVENUE, N.W., SUITE 800, WASHINGTON, DC, 20037, US

(73) Assignee: Showa Denko K.K., Minato-ku, Tokyo (JP)

(21) Appl. No.: 11/921,942

(22) PCT Filed: Jun. 7, 2006
(86) PCT No.: PCT/JP2006/311890

§ 371 Date: Dec. 11, 2007

Related U.S. Application Data
(60) Provisional application No. 60/693,090, filed on Jun. 23, 2005.

(30) Foreign Application Priority Data
Jun. 13, 2005 (JP) 2005-172201

(51) Int. Cl. G11B 5/66; C23C 14/34

(52) U.S. Cl. 428/829; 204/192.2

(57) ABSTRACT

The invention provides a perpendicular magnetic recording medium for use in a hard disk drive or a similar apparatus, a method for producing the perpendicular magnetic recording medium, and a magnetic recording and reproducing apparatus. The recording medium has excellent recording and reproducing characteristics and includes at least a non-magnetic substrate, an alignment control layer a perpendicular magnetic layer in which easy-magnetization axes are oriented in a direction virtually normal to a substrate, and a protective layer. The perpendicular magnetic layer containing Co as a predominant component, is formed of at least a first perpendicular magnetic layer formed predominantly from a material containing at least Cr, Pt, and a metal oxide or a semiconductor oxide, a second perpendicular magnetic layer formed predominantly from a CoCr alloy, and a third perpendicular magnetic layer formed predominantly from a CoCrPtB-based alloy.

### CROSS REFERENCE TO RELATED APPLICATIONS

Priority is claimed on Japanese Patent Application No. 2005-172201, filed Jun. 13, 2005. This application is an application filed under 35 U.S.C. §111(a) claiming pursuant to 35 U.S.C. §119(e) of the filing date of Provisional Application 60/693,090 on Jun. 23, 2005, pursuant to 35 U.S.C. §111(b).

### TECHNICAL FIELD

The present invention relates to a perpendicular magnetic recording medium for use in a hard disk drive or a similar apparatus, to a method for producing the perpendicular magnetic recording medium, and to a magnetic recording and reproducing apparatus. More particularly, the invention relates to such a recording medium having excellent recording and reproducing characteristics.

### BACKGROUND ART

At present, recording density of a hard disk drive (HDD)—a type of magnetic recording and reproducing apparatus—is increasing at a rate of 60% or more per year, and this tendency is expected to continue. In this connection, development of a magnetic recording head and a magnetic recording medium suitable for high recording density is under way.

Current magnetic recording medium commercial products for use in a hard disk drive are generally longitudinal magnetic recording media, in which easy-magnetization axes in a magnetic layer are oriented in parallel with a substrate. As used herein, the term “easy-magnetization axis” refers to an axis along which magnetization easily occurs. In the case of a Co-based alloy, the c-axis of the hcp structure of Co serves as the easy-magnetization axis.

In such a longitudinal magnetic recording medium, the volume of a magnetic layer per bit decreases excessively in a high-density recording state, and recording and reproducing characteristics may be impaired due to thermal fluctuation. In addition, in a high-density recording state, noise of the recording medium may increase due to a demagnetizing field formed at the boundary between recording bits.

In contrast, a so-called perpendicular magnetic recording medium, in which the easy-magnetization axis in a magnetic layer is oriented in a direction virtually normal to a substrate, is resistant to the influence of a demagnetizing field formed at the boundary between recording bits in a high-density recording state. Thus, clearly separated magnetic domains are formed, whereby noise can be reduced, and bit volume can be increased even in the case of high-density recording. Therefore, the perpendicular magnetic recording medium is not affected by thermal fluctuation. By virtue of these characteristics, perpendicular magnetic recording media have become more popular in recent years, and structures of a recording medium suitable for perpendicular magnetic recording have been proposed (see, for example, Patent Documents 1 and 2).

In recent years, in order to satisfy a demand for higher recording density of a magnetic recording medium, use of a single-pole-type head, which has excellent write-in performance with respect to a perpendicular magnetic layer, has been investigated. In order to adapt to a single-pole-type head, a magnetic recording medium has been proposed (see, for example, Patent Document 3). In the recording medium, a layer formed of a soft-magnetic material (a so-called soft magnetic underlayer (SUL)) is provided between a perpendicular magnetic layer serving as a recording layer, and a substrate, whereby transfer of magnetic flux to and from the single-pole-type head and the magnetic recording medium is enhanced.

Patent Document 1: Japanese Patent Application Laid-Open (kokai) No. 2003-187414
Patent Document 2: Japanese Patent Application Laid-Open (kokai) No. 2003-67910
Patent Document 3: Japanese Patent Application Laid-Open (kokai) 2003-168207

### DISCLOSURE OF INVENTION

However, the aforementioned magnetic recording medium provided with a soft magnetic underlayer (SUL) as disclosed in Patent Document 3 exhibits poor recording and reproducing characteristics, thermal signal loss resistance, and recording resolution. Thus, demand has arisen for a magnetic recording medium which is excellent in terms of these characteristics.

One currently employed approach is increasing the Pt content of the Co alloy forming a magnetic layer to 16 to 26 at. % so as to elevate Ku (magnetic anisotropy constant) of the Co alloy. However, when a Co alloy having a large Pt content is used to form a magnetic layer, interaction between magnetic particles contained in the magnetic layer increases excessively, thereby increasing noise, which is not suited for high-density recording.

Thus, demand has arisen for a magnetic material which increases Ku in the perpendicular direction and which suppresses noise, and for a magnetic recording medium exhibiting such characteristics.

The present invention has been accomplished under such circumstances. An object of the present invention is to provide a perpendicular magnetic recording medium which maintains excellent thermal fluctuation resistance, which attains excellent recording and reproducing characteristics (particularly media noise reduction), and which realizes recording and reproducing at high information density. Another object of the invention is to provide a method for producing the recording medium. Still another object of the invention is to provide a magnetic recording and reproducing apparatus.

The present inventors have carried out extensive studies in order to solve the aforementioned problems, and have accomplished the invention as follows.

(1) A first invention for solving the aforementioned problems is directed to a perpendicular magnetic recording medium including at least

a non-magnetic substrate, and on the substrate, an alignment control layer for aligning crystal orientation in a layer provided directly thereon,

a perpendicular magnetic layer in which easy-magnetization axes are oriented in a direction virtually normal to a substrate, and

a protective layer,

characterized in that the perpendicular magnetic layer contains Co as a predominant component and is formed of at least three layers;

a first perpendicular magnetic layer formed predominantly from a material containing at least Cr, Pt, and a metal oxide or a semiconductor oxide,

a second perpendicular magnetic layer formed predominantly from a CoCr alloy, and

a third perpendicular magnetic layer formed predominantly from a CoCrPtB-based alloy, the three layers being stacked on the substrate in this order.

(2) A second invention for solving the aforementioned problems is directed to a perpendicular magnetic recording medium as described in 1), wherein the first perpendicular magnetic layer is a granular layer, and each of the second perpendicular magnetic layer and the third perpendicular magnetic layer is a non-granular layer.
(3) A third invention for solving the aforementioned problems is directed to a perpendicular magnetic recording medium as described in 1) or 2), wherein the CoCr alloy forming the second perpendicular magnetic layer has a Cr content of 20 at. % to 37 at. %.
(4) A fourth invention for solving the aforementioned problems is directed to a perpendicular magnetic recording medium as described in 1) to 3), wherein the first perpendicular magnetic layer is formed from a material having a Cr content of 5 at. % to 28 at. % and a Pt content of 10 at. % to 20 at. %.
(5) A fifth invention for solving the aforementioned problems is directed to a perpendicular magnetic recording medium as described in 1) to 4), wherein the third perpendicular magnetic layer is formed from a material having a Cr content of 18 at. % to 28 at. % and a Pt content of 10 at. % to 20 at. %.
(6) A sixth invention for solving the aforementioned problems is directed to a perpendicular magnetic recording medium as described in 1) to 5), wherein the first perpendicular magnetic layer is formed from a material containing at least one element selected from among B, Ta, and Cu in a total amount of 8 at. % or less.
(7) A seventh invention for solving the aforementioned problems is directed to a perpendicular magnetic recording medium as described in 1) to 6), wherein the second perpendicular magnetic layer contains at least one element selected from among Ta, Pt, B, and Cu and a total amount of Cr and these elements is 20 at. % to 37 at. %.
(8) An eighth invention for solving the aforementioned problems is directed to a perpendicular magnetic recording medium as described in 1) to 7), wherein the third perpendicular magnetic layer contains at least one element selected from among B, Nd, Ta, and Cu, and the total amount of Cr, Pt, and these elements is 40 at. % or less.
(9) A ninth invention for solving the aforementioned problems is directed to a perpendicular magnetic recording medium as described in 1) to 8), which has a soft-magnetic under layer, formed from a soft-magnetic material, between the non-magnetic substrate and the alignment control layer.
(10) A tenth invention for solving the aforementioned problems is directed to a perpendicular magnetic recording medium as described in 9), which has, between the non-magnetic substrate and the soft-magnetic under layer, a hard-magnetic layer magnetic anisotropy oriented in substantially a longitudinal direction.
(11) An eleventh invention for solving the aforementioned problems is directed to a perpendicular magnetic recording medium as described in 10), wherein the hard-magnetic layer is formed from a material containing a CoSm alloy or a CoCrPtX (X: one or more species selected from among Pt, Ta, Zr, Nb, Cu, Re, Ni, Mn, Ge, Si, O, N and B) and has a coercive force of 500 [Oe] (39.5 kA/m) or more and a magnetization direction aligned with the radial direction of the substrate.
(12) A twelfth invention for solving the aforementioned problems is directed to a perpendicular magnetic recording medium as described in 1) to 11), wherein the first perpendicular magnetic layer is formed in a film formation step employing a sputtering gas pressure of 5 to 20 Pa.
(13) A thirteenth invention for solving the aforementioned problems is directed to a perpendicular magnetic recording medium as described in 1) to 12), wherein the second perpendicular magnetic layer and the third perpendicular magnetic layer are formed in a film formation step employing a sputtering gas pressure of 0.1 to 1.5 Pa.
(14) A fourteenth invention for solving the aforementioned problems is directed to a magnetic recording and reproducing apparatus including a perpendicular magnetic recording medium, and a magnetic head for recording information to and reproducing information from the perpendicular magnetic recording medium, characterized in that the perpendicular magnetic recording medium is a perpendicular magnetic recording medium as recited in any one of 1) to 13).
(15) A fifteenth invention for solving the aforementioned problems is directed to a method for producing a perpendicular magnetic recording medium including at least

a non-magnetic substrate, and on the substrate, an alignment control layer an alignment control layer for aligning crystal orientation in a layer provided directly thereon,

a perpendicular magnetic layer in which an easy-magnetization easy is oriented in a direction virtually normal to a substrate, and

a protective layer, wherein the perpendicular magnetic layer contains Co as a predominant component and is formed of at least three layers; specifically,

a first perpendicular magnetic layer formed predominantly from a material containing at least Cr, Pt, and a metal oxide or a semiconductor oxide,

a second perpendicular magnetic layer formed predominantly from a CoCr alloy, and

a third perpendicular magnetic layer formed predominantly from a CoCrPtB-based alloy, the three layers being stacked on the substrate in this order, characterized in that the first perpendicular magnetic layer is formed in a film formation step employing a sputtering gas pressure of 5 to 20 Pa.

(16) A sixteenth invention for solving the aforementioned problems is directed to a method for producing a perpendicular magnetic recording medium as described in 15), wherein the second perpendicular magnetic layer and the third perpendicular magnetic layer are formed in a film formation step employing a sputtering gas pressure of 0.1 to 1.5 Pa.

Previously, a stacked structure consisting of a granular-structure perpendicular magnetic layer containing an oxide or a nitride, and a non-granular-structure perpendicular magnetic layer was proposed so as to enhance durability and suppress spike noise (see, for example, Japanese Patent Application Laid-Open (kokai) No. 2003-168207).

One characteristic feature of the present invention is that a perpendicular magnetic layer is formed from at least one granular layer and two non-granular layers (a total of three or more layers) in order to further enhance recording and reproducing characteristics of a conventional stacked structure perpendicular magnetic recording medium.

In the case of a bi-layer structure consisting of one granular layer and one non-granular layer, suppression of spike noise and enhancement of durability have been reported. However, due to a magnetic coupling effect between two magnetic layers, medium noise of recording and reproducing is not satisfactorily reduced.

According to the present invention, an additional non-granular layer is inserted between these two layers, to thereby provide a structure having at least three layers including a granular layer, a non-granular layer (1), and a non-granular layer (2), which are stacked on the substrate in this order. The inventors have found that, through employment of this structure, magnetic coupling which would otherwise occur between the granular layer and the non-granular layer (2) is weakened by the non-granular layer (1), whereby behavior of mass of magnetic crystal grains can be prevented, leading to reduction of media noise and enhancement of SNR.

### BRIEF DESCRIPTION OF THE DRAWINGS

FIG. 1 is a cross-section showing a first embodiment of the perpendicular magnetic recording medium according to the present invention.

FIG. 2 is a graph showing an MH curve for describing characteristics of the perpendicular magnetic recording medium of the present invention.

FIG. 3 is a graph showing another MH curve for describing characteristics of the perpendicular magnetic recording medium of the present invention.

FIG. 4 is a cross-section showing a second embodiment of the perpendicular magnetic recording medium according to the present invention.

FIG. 5 is a structure of an exemplary magnetic recording and reproducing apparatus employing the perpendicular magnetic recording medium of the present invention.

FIG. 6 is a schematic view of an exemplary magnetic recording and reproducing apparatus employing the perpendicular magnetic recording medium of the present invention (plan view showing a magnetic head).

### BEST MODE FOR CARRYING OUT THE INVENTION

Embodiments of the perpendicular magnetic recording medium according to the present invention will next be described with reference to the drawings.

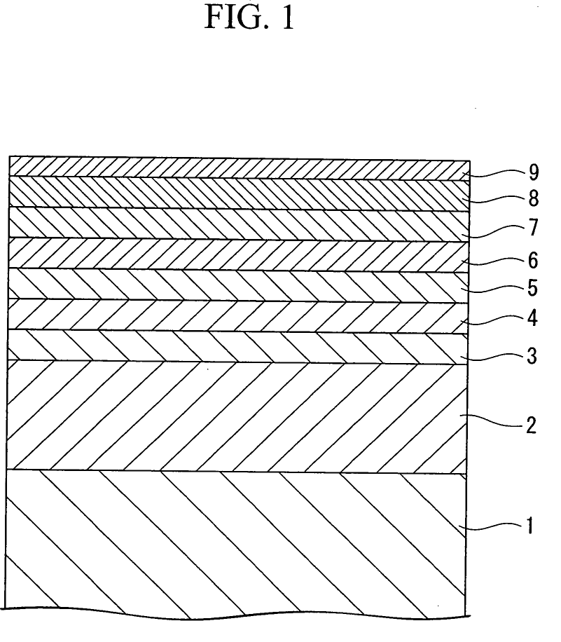

FIG. 1 shows a first embodiment of the perpendicular magnetic recording medium of the present invention. The magnetic recording medium includes a non-magnetic substrate 1, and on the substrate, a soft-magnetic under layer 2, an alignment control layer an alignment control layer 3, and intermediate layer 4, a first perpendicular magnetic layer 5, a second perpendicular magnetic layer 6, a third perpendicular magnetic layer 7, a protective layer 8, and a lubricating layer 9, which are stacked in this order.

The non-magnetic substrate 1 may be formed of a metallic substrate of a metallic material such as aluminum, or aluminum alloy, or formed of a non-metallic substrate of a non-metallic material such as glass, ceramic, silicon, silicon carbide, or carbon.

Examples of glass materials which can be employed as the substrate include glass ceramics and amorphous glass. Examples of the amorphous glass include generally used soda-lime glass, aluminocate glass, and aluminosilicate glass. Examples of the glass ceramics include lithium-containing glass ceramics. Examples of the ceramics include generally used ceramics predominantly containing aluminum oxide, aluminum nitride, silicon nitride, etc., and such ceramics reinforced with fiber material.

The non-magnetic substrate 1 may be formed of any of the aforementioned metallic or non-metallic substrates on which substrate an NiP layer is formed through plating or sputtering.

In the perpendicular magnetic recording medium of the present invention, a soft-magnetic under layer under layer 2 is preferably provided under the crystal orientation alignment layer 3. The soft-magnetic under layer under layer 2 increases a perpendicular component of a magnetic flux provided by the magnetic head with respect to the substrate and more strongly fixes magnetization, in a direction normal to the non-magnetic substrate 1, of information recording layers; i.e., the first perpendicular magnetic layer 5, the second perpendicular magnetic layer 6, and the third magnetic recording layer (3) 7. These effects are more remarkable particularly when a single-pole-type head for perpendicular recording is employed as a magnetic head for recording and reproducing information.

The aforementioned soft-magnetic under layer 2 is formed from a soft-magnetic material, which may contain Fe, Ni, or Co. Examples of the material include FeCo-based alloys (FeCo, FeCoV), FeNi-based alloys (FeNi, FeNiMo, FeNiCr, FeNiSi), FeAl-based alloys (FeAl, FeAlSi, FeAlSiCr, FeAlSiTiRu, FeAlO), FeCr-based alloys (FeCr, FeCrTi, FeCrCu), FeTa-based alloys (FeTa, FeTaC, FeTaN), FeMg-based alloys (FeMgO), FeZr-based alloys (FeZrN), FeC-based alloys, FeN-based alloys, FeSi-based alloys, FeP-based alloys, FeNb-based alloys, FeHf-based alloys, and FeB-based alloys.

Alternatively, the soft-magnetic material may be a material containing Fe in an amount of 60 at % or more and a microcrystalline structure of FeAlO, FeMgO, FeTaN, FeZrN, etc., or a material having a granular structure in which microcrystalline grains are dispersed in the matrix.

The soft-magnetic under layer 2 may also be formed of an amorphous Co alloy containing Co in an amount of 80 at % or more and at least one element selected from among Zr, Nb, Ta, Cr, Mo, etc. Examples of preferred Co alloys include CoZr, CoZrNb, CoZrTa, CoZrCr, and CoZrMo-based alloys.

The soft-magnetic under layer 2 preferably has a coercive force Hc of 200 [Oe] or less (more preferably 50 [Oe] or less). When the coercive force Hc is higher than the upper limit, soft-magnetic characteristics become poor, and the reproduction signal wave changes from a rectangular wave to a biased wave, which is not preferred.

The soft-magnetic under layer 2 preferably has a saturated magnetic flux density Bs of 0.6 T or more (preferably 1 T or more). When the Bs is less than the lower limit, the reproduction signal wave changes from a rectangular wave to a biased wave, which is not preferred.

The soft-magnetic under layer 2 preferably has a thickness of 20 to 400 nm. When the thickness falls within the range, the reproduction signal wave is not biased.

The product (Bs·t (T·nm)) of saturated magnetic flux density Bs (T) of the soft-magnetic under layer 2 and thickness of the soft-magnetic under layer 2 (t(nm)) is preferably 20 (T·nm) or more (more preferably 40 (T·nm) or more). When the Bs·t is less than the lower range, the reproduction signal wave is biased, and OW characteristics are impaired, which is not preferred.

The alignment control layer 3 regulates alignment and grain size of the intermediate layer 4 provided directly thereon, the first perpendicular magnetic layer 5, and the second perpendicular magnetic layer 6.

No particular limitation is imposed on the material for forming the alignment control layer 3. However, materials having an hcp structure, an fcc structure, or an amorphous structure are preferred. Of these, Ru-based alloys, Ni-based alloys, and Co-based alloys are particularly preferred.

In the perpendicular magnetic recording medium of the embodiment, the alignment control layer 3 preferably has a thickness of 0.5 to 40 nm (more preferably 1 to 20 nm). When the alignment control layer 3 has a thickness of 0.5 to 40 nm (more preferably 1 to 20 nm), magnetization is aligned considerably highly in the perpendicular direction in the perpendicular magnetic layer 5, and the distance between the magnetic head and the soft-magnetic under layer 2 can be shortened during recording, whereby recording and reproducing characteristics can be enhanced without reducing resolution of the reproduction signal. When the thickness is less than the lower limit, magnetization is less aligned with the perpendicular direction in the perpendicular magnetic layer 5, whereby recording and reproducing characteristics and thermal fluctuation resistance are impaired. In contrast, when the thickness is in excess of the upper limit, the magnetic grain size of the perpendicular magnetic layer 5 increases, possibly impairing noise characteristics, which is not preferred. In addition, the distance between the magnetic head and the soft-magnetic under layer 2 increases during recording, resulting in a drop in resolution of reproduction signal or reproduction output, which is not preferred.

The surface profile of the alignment control layer 3 considerably influences the surface profiles of the perpendicular magnetic layer 5 and the protective layer 6. Therefore, in order to reduce surface roughness of the magnetic recording medium and lower the flying height of the magnetic head during recording and reproducing, the mean surface roughness Ra of the alignment control layer 3 is preferably controlled to 2 nm or less. Through the control of the Ra to 2 nm or less, surface roughness of the magnetic recording medium can be reduced, and the flying height of the magnetic head during recording and reproducing can be sufficiently lowered, whereby recording density can be enhanced.

The gas for forming the alignment control layer 3 may contain oxygen or nitrogen. For example, in the case the layer is formed through sputtering, the process gas to be employed is preferably formed from argon containing about 0.05 to 50% by volume (more preferably about 0.1 to 20% by volume) of oxygen or argon containing about 0.01 to 20% by volume (more preferably about 0.02 to 10% by volume) of nitrogen.

Between the alignment control layer 3 and the first perpendicular magnetic layer 5, an intermediate layer 4 may be provided. Through provision of the intermediate layer 4, perpendicular alignment in the first perpendicular magnetic layer 5 and the second perpendicular magnetic layer 6 can be enhanced. Thus, coercive force of the first perpendicular magnetic layer 5, the second perpendicular magnetic layer 6, and the third perpendicular magnetic layer 7 can be increased, whereby recording and reproducing characteristics and thermal fluctuation resistance can be enhanced.

The intermediate layer 4 is preferably formed from a material having an hcp structure. Specifically, the intermediate layer 4 is preferably formed from Ru, an Ru alloy, a CoCr alloy, a CoCrX1alloy, or a CoX1alloy (X1: one or more elements selected from among Pt, Ta, Zr, Ru, Nb, Cu, Re, Ni, Mn, Ge, Si, O, N, and B).

In order to prevent impairment of recording and reproducing characteristics caused by the coarsening of magnetic grains in the first perpendicular magnetic layer 5 and to prevent reduction of recording resolution caused by increasing in the distance between the magnetic head and the soft-magnetic under layer 2, the intermediate layer 4 preferably has a thickness of 20 nm or less (more preferably 10 nm or less).

In the first perpendicular magnetic layer 5, the easy-magnetization axis is oriented in a direction virtually normal to a substrate. The magnetic layer contains Co as a predominant component, and is formed from a material containing at least Cr and Pt. Preferably, the Cr content is 5 to 28 at. % (more preferably 19 to 24 at. %), and the Pt content is 10 to 20 at. % (more preferably 13 to 18 at. %).

When the first perpendicular magnetic layer 5 has a Cr content less than 5 at. %, the grain boundary layer formed between magnetic grains becomes thinner due to segregation of Cr, and magnetic interaction between grains increases, thereby facilitating to increase the magnetic grain size. Thus, noise increases during recording and reproducing, thereby failing to obtain a signal/noise ratio (S/N) suitable for high-density recording.

When the first perpendicular magnetic layer 5 has a Cr content in excess of 28 at. %, segregation of Cr in the grain boundary layer is incomplete, and a large amount of Cr remains in magnetic grains. Thus, coercive force in the perpendicular direction and the ratio (Mr/Ms) of residual magnetization (Mr) to saturation magnetization (Ms) tend to decrease. In addition, crystal alignment of magnetic grains is impaired, and the ratio (Hc-v)/(Hc-i) of perpendicular coercive force (Hc-v) and longitudinal coercive force (Hc-i) may decrease.

When the first perpendicular magnetic layer 5 has a Pt content less than 10 at. %, magnetic anisotropy constant (Ku) required for the perpendicular magnetic layer cannot be obtained, resulting in thermal instability of magnetization, whereas when the Pt content is in excess of 20 at. %, segregation of Cr in the magnetic layer is impeded, and a layer of the fcc structure is formed in the magnetic layer, possibly resulting in lowering coercive force. Therefore, the Pt content preferably falls within the above range.

The elements B, Ta, and Cu promote segregation of Cr in the magnetic layer to thereby reduce magnetic interaction between grains and magnetic grain size, whereby noise reduction can be attained during recording and reproducing. These elements are preferably added to the first perpendicular magnetic layer 5 in a total amount of 8 at. % or less. When the total amount is in excess of 8 at. %, these elements remain in magnetic grains, thereby lowering perpendicular coercive force and the ratio (Mr/Ms) of residual magnetization (Mr) to saturation magnetization (Ms), which is not preferred.

The second perpendicular magnetic layer 6 may be formed from a magnetic material, for example, a Co—Cr alloy (Cr content: 20 at. % to 37 at. %, preferably 25 at. % to 35 at. %). Such an alloy may further contain a very small amount of a third element such as Pt, B, Ta, Nb, Zr, Mo, or Mn. The second perpendicular magnetic layer preferably exhibits ferromagnetism in the as-formed state. The aforementioned upper limit of the Cr content is determined in consideration of maintaining the ferromagnetism of the Co—Cr alloy film. When the Cr content is less than 20 at. %, saturation magnetization of the second perpendicular magnetic layer increases, thereby failing to attain a sufficient effect of relaxing magnetic bonding between the first perpendicular magnetic layer and the third perpendicular magnetic layer, resulting in poor improvement in recording and reproducing characteristics. Differing from the first perpendicular magnetic layer, the second perpendicular magnetic layer preferably contains no oxide, nitride, or a similar substance.

The third perpendicular magnetic layer 7 may be formed from a magnetic material, for example, a Co—Cr—Pt alloy (Cr content: 18 at. % to 28 at. %, Pt content: 10 at. % to 20 at. %). In addition to the first perpendicular magnetic layer 5, the second perpendicular magnetic layer 6, and the third perpendicular magnetic layer 7, which form the perpendicular magnetic layer, additional perpendicular magnetic layers (4) and (5) may be formed to thereby form a perpendicular magnetic recording layer of a stacked structure including four or more layers. When the perpendicular magnetic layer is formed of four or more magnetic layers, at least three layers of the first perpendicular magnetic recording layer (1) 5, the second perpendicular magnetic layer 6, and the third perpendicular magnetic layer preferably exhibit perpendicular magnetic anisotropy.

In addition to the aforementioned materials, the third perpendicular magnetic layer may be formed from any of the following magnetic materials: CoCrPt-based alloys, CoCr-based alloys, CoCrPtB-based alloys, CoCrPtBNd-based alloys, CoCrPtCu-based alloys, a stacked layer of a Co-based alloy (e.g., CoCr or CoB) and a Pd-based alloy (e.g., PdB), an amorphous material such as TbFeCo, and CoCrPtCu-based materials.

When a multi-layer structure is employed, an intermediate layer formed from a non-magnetic material may be inserted between magnetic layers. Examples of the non-magnetic material include non-magnetic metallic materials having an hcp structure; and non-magnetic metallic materials, metal oxide materials, and metal nitride materials each having a bcc structure, an fcc structure, or an amorphous structure.

The first perpendicular magnetic layer 5 preferably has a thickness of 3 to 60 nm (more preferably 5 to 40 nm). When the first perpendicular magnetic layer 5 has a thickness less than the lower limit, sufficient magnetic flux cannot be obtained, thereby reducing reproduction output, whereas when the thickness of the perpendicular magnetic layer 5 is in excess of the upper limit, magnetic grains in the first perpendicular magnetic layer 5 are coarsened, thereby impairing recording and reproducing characteristics, which is not preferred.

As described hereinabove, the perpendicular magnetic layer employed in the present invention is formed of the first perpendicular magnetic layer having a granular structure, the second perpendicular magnetic layer formed of a typical alloy magnetic thin film, and the third perpendicular magnetic layer formed of a typical alloy magnetic thin film, which are stacked on the substrate in this order. As used herein, the term “granular structure” of the first perpendicular magnetic layer refers to a structure, for example, formed of a typical alloy (e.g., Co—Cr—Pt-based alloy) thin film in which microcrystalline particles or micro-amorphous particles of oxide are present. Typically, oxide micro-particles are dispersed in the alloy phase. Depending on the film formation conditions and choice of material, these oxide particles do not disperse but may surround base alloy crystal grains. Instead of adding stable oxide such as SiO₂, another technique is also known. Specifically, when a film is formed from a base alloy in an oxygen atmosphere under predetermined conditions, a metal oxide film is formed. In this case, the formed film has a structure in which oxide is dispersed; i.e., a granular structure. In the present invention, granular structures formed through any technique may be employed.

Next, the effects of the aforementioned stacked magnetic layer including at least three layers: the granular layer, the non-granular layer, and the non-granular layer, the layers being stacked in this order.

The first perpendicular magnetic layer, which is a granular layer, serves as a main recording layer for perpendicular magnetic recording in a magnetic recording medium. Since the film has a granular structure, exchange interaction between magnetic crystal grains is mitigated, thereby suppressing media noise. On the other hand, independent behavior of the crystal grains elevates coercive force Hc to a sufficiently high level but tend to lower nucleation magnetic field Hn. In perpendicular magnetic recording, Hn is required to be elevated to a certain level so as to avoid effects of adjacent tracks.

The third perpendicular magnetic layer, which is a non-granular layer, is generally formed from a material having a relatively high saturation magnetization Bs with respect to the first perpendicular magnetic layer. Through stacking the third perpendicular magnetic layer directly on the first perpendicular magnetic layer, interaction between magnetic crystal grains is enhanced, whereby Hn can be increased. In this case, reduction in Hc and increase in media noise readily occur. Thus, in the present invention, a new second perpendicular magnetic layer is inserted between the first perpendicular magnetic layer and the third perpendicular magnetic layer, whereby the interaction between the first and third perpendicular magnetic layers (1) and (3) is controlled. From the gist of the present invention that magnitude of magnetic interaction is controlled, the second perpendicular magnetic layer preferably has a saturation magnetic flux density Bs relatively smaller than that of the third perpendicular magnetic layer. Through appropriate control of the thickness of the second perpendicular magnetic layer, magnetic characteristics and recording and reproducing characteristics can be controlled to a certain degree.

According to the present invention, the three layers of the first perpendicular magnetic layer 5, the second perpendicular magnetic layer 6, and the third perpendicular magnetic layer 7 exhibit, in the stacked state, a ratio (Mr/Ms) of residual magnetization (Ms) to saturation magnetization (Mr) of 0.85 or higher (preferably 0.95 or higher). When the magnetic recording medium has a Mr/Ms less than 0.85, reverse magnetic domain nucleation field decreases, resulting in poor thermal fluctuation resistance, which is not preferred.

According to the present invention, the three layers of the first perpendicular magnetic layer 5, the second perpendicular magnetic layer 6, and the third perpendicular magnetic layer 7 exhibit, in the stacked state, an activation magnetic moment (vIsb) represented by the product of activation volume (v) and saturation magnetic moment (Is) of 0.3×10⁻¹⁵ emu to 0.8×10⁻¹⁵ emu (preferably 0.4×10⁻¹⁵ emu to 0.7×10⁻¹⁵ emu). When vIsb is less than 0.3×10⁻¹⁵ emu, magnetic cluster size excessively decreases, causing thermal instability. In this case, thermal signal loss readily occurs, which is not preferred as a magnetic recording medium. When vIsb is in excess of 0.8×10⁻¹⁵ emu, noise excessively increases during recording and reproducing, whereby a signal/noise ratio ((S/N) required for high-density recording cannot be obtained, which is not preferred.

The three layers of the first perpendicular magnetic layer, the second perpendicular magnetic layer, and the third perpendicular magnetic layer preferably exhibit, in the stacked state, a perpendicular coercive force (Hc-v) of 2,500 [Oe] or more. When the magnetic recording medium has a coercive force less than 2,500 [Oe], the medium is not suited for high-density recording and has poor thermal fluctuation resistance.

The three layers consisting of the first perpendicular magnetic layer, the second perpendicular magnetic layer, and the third perpendicular magnetic layer preferably exhibit, in the stacked state, a perpendicular magnetic anisotropy represented by a ratio ((Hc-v)/(Hc-i)) of perpendicular coercive force (Hc-v) to longitudinal coercive force (Hc-i) of 5 or more. When Hc-v/Hc-i is less than 5, the magnetic layers have poor crystal alignment, which means that the easy-magnetization axis of Co (i.e., C-axis) is not aligned with the direction normal to the substrate. As a result, coercive force (Hc-v), Mr/Ms ratio, and reverse magnetic domain nucleation field (−Hn) tend to be reduced. In addition, the magnetization state is thermally instable, thereby causing thermal signal loss and increased noise during recording and reproducing, which is not preferred.

Each of the first perpendicular magnetic layer 5, the second perpendicular magnetic layer 6, and the third perpendicular magnetic layer 7 preferably exhibits a reverse magnetic domain nucleation field (−Hn) of 0 to 2,000 [Oe] (more preferably 0 to 1,500 [Oe]). The magnetic recording medium exhibiting a reverse magnetic domain nucleation field (−Hn) less than 0 has poor thermal fluctuation resistance, which is not preferred.

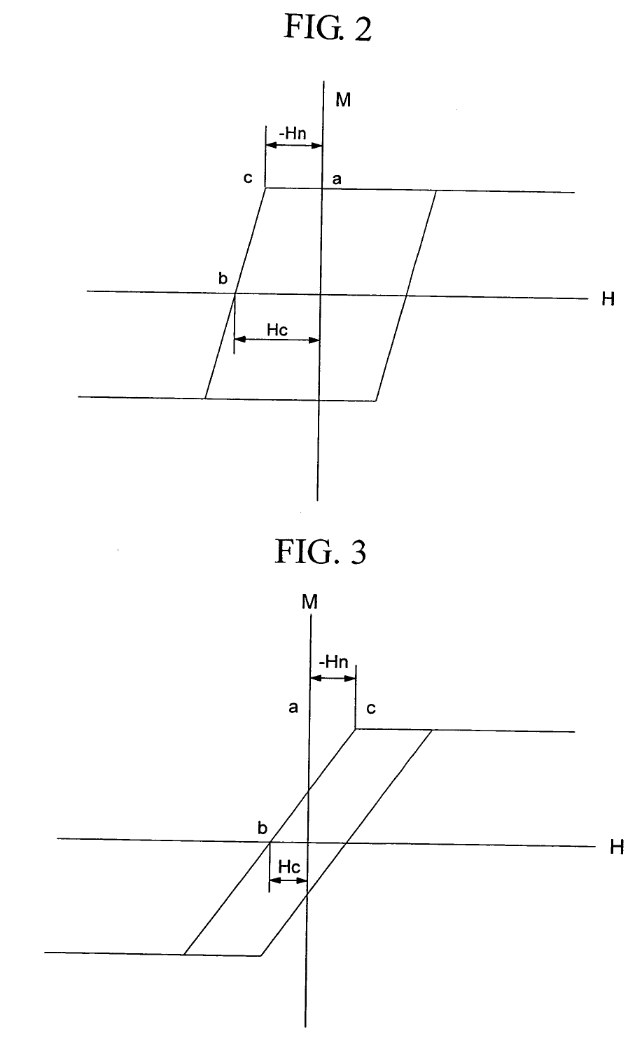

As shown in FIG. 2, reverse magnetic domain nucleation field (−Hn) is determined on an MH curve obtained by means of a VSM or similar means. Specifically, when a point at which external magnetic field becomes 0 as the external magnetic field is reduced at the level of magnetization saturation is represented by point “a,” a point at which magnetization is 0 on the MR curve is represented by point “b,” and the intersection point of the extension of the tangential line at point “b” and the saturation magnetization line is represented by point “c,” the reverse magnetic domain nucleation field (−Hn) can be expressed by the distance [Oe] between of point “c” and the Y axis. The reverse magnetic domain nucleation field (−Hn) assumes a positive value when point “c” is present in a region where external magnetic field is a negative value (see FIG. 2), whereas reverse magnetic domain nucleation field (−Hn) assumes a negative value when point “c” is present in a region where external magnetic field is a positive value (see FIG. 3).

In the present specification, “aligned in the direction virtually normal to the substrate” refers to a state where coercive force measured by means of, for example, a VSM in the direction normal to the substrate is greater than that measured in the longitudinal direction with respect to the substrate.

The protective layer 8 prevents corrosion of the first perpendicular magnetic layer 5, the second perpendicular magnetic layer 6, and the third perpendicular magnetic layer 7, and damage of the surface of the recording medium upon contact with a magnetic head. The protective layer may be formed from conventionally known materials containing carbon, SiO₂, or ZrO₂.

The protective layer 8 preferably has a thickness of 1 to 10 nm from the viewpoint of reduction of the distance between the head and the medium and high-density recording.

The lubricant 9 is preferably perfluoropolyether, fluroinated alcohol, fluorinated carboxylic acid, etc.

The perpendicular magnetic recording medium of the present invention includes at least a non-magnetic substrate, and on the substrate, an alignment control layer an alignment control layer for aligning crystal orientation in a layer provided directly thereon, a perpendicular magnetic layer in which easy-magnetization axes are oriented in a direction virtually normal to a substrate, and a protective layer, and is characterized in that the perpendicular magnetic layer contains Co as a predominant component, is formed from a material containing at least Cr and Pt, and exhibits a ratio (Mr/Ms) of perpendicular (with respect to the substrate) residual magnetization (Mr) to saturation magnetization (Ms) of 0.85 or higher and an activation magnetic moment represented by the product of activation volume and saturation magnetic moment of 0.3×10⁻¹⁵ emu to 0.8×10⁻¹⁵ emu. Therefore, resolution of recording and reproducing characteristics and thermal stability of magnetization of the magnetic recording medium can be enhanced without increasing noise during recording and reproducing.

Next will be described one exemplary method for producing the perpendicular magnetic recording medium having the aforementioned layer configuration.

In the production of the perpendicular magnetic recording medium having the aforementioned layer configuration, a soft-magnetic under layer 2, an alignment control layer an alignment control layer 3, an intermediate layer 4, a first perpendicular magnetic layer 5, a second perpendicular magnetic layer 6, and a third perpendicular magnetic layer 7 are sequentially formed on a non-magnetic substrate 1 through sputtering, vacuum vapor deposition, ion-plating, etc. Subsequently, a protective layer 8 is formed preferably through plasma CVD, the ion-beam method, or sputtering.

The non-magnetic substrate 1 may be formed of a metallic substrate of a metallic material such as aluminum, or aluminum alloy, or formed of a non-metallic substrate of a non-metallic material such as glass, ceramic, silicon, silicon carbide, or carbon.

Examples of glass materials which can be employed as the substrate include glass ceramics and amorphous glass. Examples of the amorphous glass include generally used soda-lime glass, aluminocate glass, and aluminosilicate glass. Examples of the glass ceramics include lithium-containing glass ceramics. Examples of the ceramics include generally used ceramics predominantly containing aluminum oxide, aluminum nitride, silicon nitride, etc., and such ceramics reinforced with fiber material.

The non-magnetic substrate 1 may be formed of any of the aforementioned metallic or non-metallic substrates on which substrate an NiP layer is formed through plating or sputtering.

The non-magnetic substrate preferably has a mean surface roughness Ra of 2 nm (20 Å) or less, more preferably 1 nm or less, from the viewpoint of performing high-density recording with a low flying height.

The non-magnetic substrate preferably has a surface [micro-waviness (Wa) of 0.3 nm or less (preferably 0.25 [nm] or less), from the viewpoint of performing high-density recording with a low flying height. At least one of a chamfer section of the end surface and a side surface of the non-magnetic substrate preferably has a surface roughness (Ra) of 10 nm or less (more preferably 9.5 nm or less), from the viewpoint of flying stability of a magnetic head. The micro-waviness (Wa) can be determined by means of, for example, a surface roughness meter (P-12, product of KLM-Tencor) as an average surface roughness value within a measurement depth of 80 μm.

The non-magnetic substrate is washed in accordance with needs, and placed in a chamber of a film-forming apparatus. In accordance with needs, the non-magnetic substrate is heated by means of, for example, a heater to 100 to 400° C. On the non-magnetic substrate 1, the soft-magnetic under layer 2, the alignment control layer 3, the intermediate layer 4, the first perpendicular magnetic layer 5, the second perpendicular magnetic layer 6, and the third perpendicular magnetic layer 7 are formed through DC or RF magnetron sputtering of sputtering targets of the same materials as forming the component layers. For example, formation of the layers through sputtering is performed under the following conditions. The chamber employed for film formation is evacuated to a vacuum of 10⁻⁴ to 10⁻⁷ Pa. The substrate is placed in the chamber, and sputtering for film formation is carried out through discharge with introduction of a sputtering gas such as Ar. The input power is adjusted to 0.2 to 2.0 kW. Through controlling discharge time and input power, a film having a thickness of interest can be produced.

Through controlling discharge time and input power, the soft-magnetic under layer 2 is preferably formed to have a thickness of 30 to 400 nm.

The soft-magnetic under layer 2 is preferably formed by use of a sputtering target formed made of a soft-magnetic material, since the soft-magnetic under layer can be readily formed. Examples of the soft-magnetic material include FeCo-based alloys (e.g., FeCo and FeCoV), FeNi-based alloys (e.g., FeNi, FeNiMo, FeNiCr, and FeNiSi), FeAl-based alloys (e.g., FeAl, FeAlSi, FeAlSiCr, FeAlSiTiRu, and FeAlO), FeCr-based alloys (e.g., FeCr, FeCrTi, and FeCrCu), FeTa-based alloys (e.g., FeTa, FeTaC, and FeTaN), FeMg-based alloys (e.g., FeMgO), FeZr-based alloys (e.g., FeZrN), FeC-based alloys, FeN-based alloys, FeSi-based alloys, FeP-based alloys, FeNb-based alloys, FeHf-based alloys, FeB-based alloys, and Fe alloys containing 60 at. % or more Fe (FeAlO, FeMgO, FeTaN, and FeZrN). Examples of preferred soft-magnetic materials include CoZr, CoZrNb, CoZrTa, CoZrCr, and CoZrMo-based alloys, which has an amorphous structure and a Co content of 80 at. % or more and contains at least one element selected from among Zr, Nb, Ta, Cr, Mo, etc.

The aforementioned targets are alloy targets produced through melting or sintered alloy targets.

After formation of the soft-magnetic under layer 2, the alignment control layer 3 is formed through controlling discharge time and input power so as to have a thickness of 0.5 to 40 nm (preferably 1 to 20 nm). Examples of the sputtering target material for forming the alignment control layer include Pd and Pd alloys, Pt and Pt alloys, Ru-based alloys, Ni-based alloys, and Co-based alloys.

After formation of the alignment control layer 3, the intermediate layer 4 having a thickness of 20 nm or less is formed by use of a sputtering target of the same material under the same sputtering conditions. Examples of the target material include Ru and Ru-based alloys, Ni-based alloys, and Co-based alloys.

After formation of the intermediate layer 4, the first perpendicular magnetic layer 5 having a thickness of 3 to 40 nm is formed through sputtering by use of a sputtering target made of the same material as the magnetic layer material under the same sputtering conditions. Examples of the sputtering target material include CoCrPt—SiO₂-based material and CoCrPt—Cr₂O₃-based material made of oxide-particle-dispersed CoCrPt alloy; CoCrPt alloys such as CoCrPt-based alloys, CoCrPtNd-based alloys, CoCrPtBNd-based alloys, CoCrPtTaNd-based alloys, CoCrPtCuNd-based alloys, CoCrPtBCuNd-based alloys, CoCrPt-based alloys, CoCrPtB-based alloys, and CoCrPtCu-based alloys; stacked layer material with a Pd-based alloy (e.g., PdB or Pd—SiO₂); amorphous materials such as TbFeCo; and CoCrPtCu-based materials.

In addition to Cr and Pt, at least one element selected from among B, Ta, and Cu is preferably added to the target material.

The perpendicular magnetic layer which contains Co as a predominant component and is formed from a material containing at least Cr and Pt and which exhibits a ratio (Mr/Ms) of perpendicular (with respect to the substrate) residual magnetization (Mr) to saturation magnetization (Ms) of 0.85 or higher and an activation magnetic moment represented by the product of activation volume and saturation magnetic moment of 0.3×10⁻¹⁵ emu to 0.8×10⁻¹⁵ emu is formed under, for example, the following sputtering conditions.

A material which contains Co as a predominant component and is formed from a material which containing at least Cr and Pt is used as a target. The chamber employed for film formation is evacuated to a vacuum of 10⁻⁴ to 10⁻⁷ Pa. The substrate is placed in the chamber, and sputtering for film formation is carried out through discharge with introduction of Ar serving as a sputtering gas. The input power is adjusted to 0.2 to 2.0 kW. Through controlling discharge time and input power, a film having a thickness of interest can be produced.

The first perpendicular magnetic layer 5 is preferably formed at a sputtering gas pressure of 5 to 20 Pa (more preferably 5 to 15 Pa).

After formation of the first perpendicular magnetic layer 5, the second perpendicular magnetic layer 6 having a thickness of 10 nm or less is formed through sputtering by use of a sputtering target made of the same material as the magnetic layer material under the same sputtering conditions. Examples of the sputtering target material include CoCr-based alloys. The CoCr alloys have a Cr content of appropriately 20 at. % to 37 at. %, preferably 25 at. % to 30 at. %.

The second perpendicular magnetic layer 6 may further contain, in addition to Co and Cr, a very small amount of an element(s) selected from among Ta, Pt, B, and Cu. The total amount of Cr and these additional elements is appropriately 20 at. % to 37 at. %.

After formation of the second perpendicular magnetic layer 6, the third perpendicular magnetic layer 7 having a thickness of 10 nm or less is formed through sputtering by use of a sputtering target made of the same material as the magnetic layer material under the same sputtering conditions. Examples of the sputtering target material include CoCrPtB-based alloys. The Cr content is appropriately 18 at. % to 28 at. %, and the Pt content is appropriately 10 at. % to 20 at. %.

The third perpendicular magnetic layer may further contain at least one element selected from among B, Nd, Ta, and Cu. The total amount of Cr and these additional elements is appropriately 40 at. % or less.

In the formation of the second perpendicular magnetic layer 6 and the third perpendicular magnetic layer, sputtering gas pressure is preferably 0.1 Pa to 1.5 Pa.

After formation of the magnetic layers, a protective film is formed through a known method such as sputtering, plasma CVD, or a combination thereof. The protective film may be formed from carbon as a predominant component.

In accordance with needs, a lubricating layer is formed on the protective layer by applying a fluorine-containing lubricant made of perfluoropolyether through dipping, spin-coating, or a similar method.

In the perpendicular magnetic recording medium produced according to the present invention, the perpendicular magnetic layer contains Co as a predominant component, is formed from a material containing at least Cr and Pt and exhibits a ratio (Mr/Ms) of perpendicular (with respect to the substrate) residual magnetization (Mr) to saturation magnetization (Ms) of 0.85 or higher and an activation magnetic moment represented by the product of activation volume and saturation magnetic moment of 0.3×10⁻¹⁵ emu to 0.8×10⁻¹⁵ emu. Therefore, resolution of recording and reproducing characteristics and thermal stability of magnetization of the magnetic recording medium can be enhanced without increasing noise during recording and reproducing.

According to the method of the present invention for producing a perpendicular magnetic recording medium by use of the aforementioned sputtering targets, a magnetic recording medium characterized in that the first perpendicular magnetic layer 5 contains Co as a predominant component and is formed from a material containing at least Cr and Pt and exhibits a ratio (Mr/Ms) of perpendicular (with respect to the substrate) residual magnetization (Mr) to saturation magnetization (Ms) of 0.85 or higher and an activation magnetic moment represented by the product of activation volume and saturation magnetic moment of 0.3×10⁻¹⁵ emu to 0.8×10⁻¹⁵ emu can be readily produced.

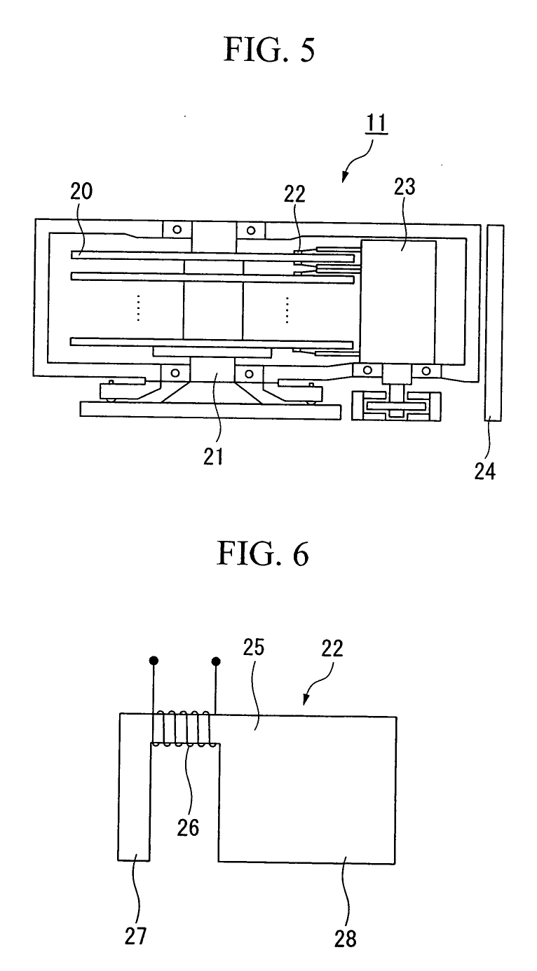

FIG. 5 shows an exemplary magnetic recording and reproducing apparatus employing the aforementioned perpendicular magnetic recording medium.

The magnetic recording and reproducing apparatus 11 shown in FIG. 5 includes a perpendicular magnetic recording medium 20 having a layer configuration shown in FIG. 1, a spindle motor 21 for rotating the perpendicular magnetic recording medium 20, a magnetic head 22 for recording information in and reproducing information from the perpendicular magnetic recording medium 20 (see FIG. 6), a head actuator 23 for moving the magnetic head 22 relative to the magnetic recording medium 20, and a recording and reproducing signal processing system 24. The recording and reproducing signal processing system 24 is provided such that data input from the outside is processed to transmit a record signal to the magnetic head 22 and that a reproduction signal obtained from the magnetic head 22 is processed to transmit data to the outside. The magnetic head 22 employed in the perpendicular magnetic recording medium of the present invention may be a head suitable for higher-density recording having a GMR element based on giant magnetoresistance (GMR) serving as a reproduction element.

The aforementioned magnetic recording and reproducing apparatus 11 employs the perpendicular magnetic recording medium 20, characterized in that the perpendicular magnetic layer contains Co as a predominant component and is formed from a material containing at least Cr and Pt and exhibits a ratio (Mr/Ms) of perpendicular (with respect to the substrate) residual magnetization (Mr) to saturation magnetization (Ms) of 0.85 or higher and an activation magnetic moment represented by the product of activation volume and saturation magnetic moment of 0.3×10⁻¹⁵ emu to 0.8×10⁻¹⁵ emu. Therefore, resolution of recording and reproducing characteristics and thermal stability of magnetization of the magnetic recording medium can be enhanced without increasing noise during recording and reproducing. Thus, the magnetic recording and reproducing apparatus is suitable for high recording density.

As described hereinabove, the embodiment of the perpendicular magnetic recording medium includes at least a non-magnetic substrate, and on the substrate, an alignment control layer an alignment control layer for aligning crystal orientation in a layer provided directly thereon, a perpendicular magnetic layer in which easy-magnetization axes are oriented in a direction virtually normal to a substrate, and a protective layer, wherein the perpendicular magnetic layer contains Co as a predominant component and is formed of at least three layers of a first perpendicular magnetic layer formed predominantly from a material containing at least Cr, Pt, and a metal oxide or a semiconductor oxide, a second perpendicular magnetic layer formed predominantly from a CoCr alloy, and a third perpendicular magnetic layer formed predominantly from a CoCrPtB-based alloy, the three layers being stacked on the substrate in this order.

Through employment of the magnetic recording medium, magnetic coupling between the first perpendicular magnetic layer and the third perpendicular magnetic layer is weakened by the second perpendicular magnetic layer, while excellent thermal fluctuation resistance is maintained. Thus, media noise can be reduced, while high ferromagnetic property is maintained.

Therefore, a perpendicular magnetic recording medium which exhibits enhanced recording and reproducing characteristics and which can record and reproduce information at high density can be produced.

In perpendicular magnetic recording media, materials containing a metal oxide or a semiconductor oxide are widely employed. Addition of Pt to a CoCr-based alloy, which has been employed in magnetic recording media, increases anisotropic magnetic field energy. In addition, the added oxide phase surrounds magnetic crystal grains, whereby intergranular exchange interaction is mitigated, leading to media noise reduction. When the first perpendicular magnetic layer is formed from such a material, basic performance required for a recording layer can be ensured. When the third perpendicular magnetic layer is formed from a CoCrPtB-based alloy thin film, which is known to exhibit considerably low noise among non-granular films, an undesired noise increase can be prevented. The second perpendicular magnetic layer, which buffers exchange interaction between the first perpendicular magnetic layer and the third perpendicular magnetic layer, is required to have a continuous and epitaxial crystal structure in a magnetic layer. Therefore, among Co-based alloy thin films having a Co-based hexagonal close-packed structure, a CoCr-based alloy thin film having a considerably high crystallinity is employed so as not to impair the entire crystal structure of the perpendicular magnetic layer.

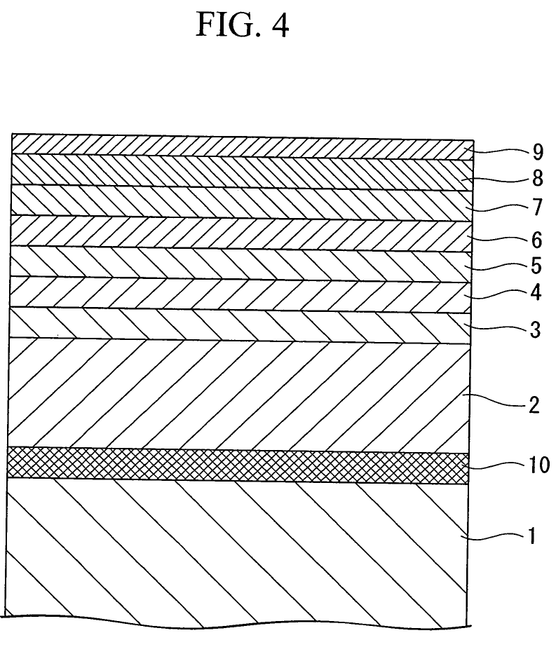

FIG. 4 shows a second embodiment of the perpendicular magnetic recording medium according to the present invention. A hard-magnetic layer 10 in which magnetic anisotropy is oriented virtually in a longitudinal direction may be provided between the non-magnetic substrate 1 and the soft-magnetic under layer 2.

The hard-magnetic layer 10 is preferably formed from a CoSm alloy or a CoCrPtX (X: one or more species selected from among Pt, Ta, Zr, Nb, Cu, Re, Ni, Mn, Ge, Si, O, N, and B).

The hard-magnetic layer 10 preferably has a coercive force Hc of 500 [Oe] or more (more preferably 1,000 [Oe] or more).

The hard-magnetic layer 10 preferably has a thickness of 150 nm or less (more preferably 70 nm or less). When the thickness of the hard-magnetic layer 10 is in excess of 150 nm, the alignment control layer 3 has an increased mean surface roughness Ra, which is not preferred.

The hard-magnetic layer 10 preferably has a magnetization direction being aligned with the radial direction of the substrate through exchange coupling with the soft-magnetic under layer 2. As a result, magnetization in the soft magnetic layer 2 is aligned with the radial direction through exchange coupling, and the magnetic field for writing in is perpendicular to the direction of magnetization, whereby the exchange coupling state during recording and reproducing is more stabilized. As a result, noise generation can be prevented, which is preferred.

Through provision of the hard-magnetic layer 10, formation of giant magnetic domains in the soft-magnetic under layer 2 can be effectively prevented. Thus, generation of spike noise by domain walls is prevented, thereby sufficiently reducing the error rate during recording and reproducing.

In order to regulate the alignment in the hard-magnetic layer 10, a Cr alloy material or a B2 structure material may be provided between the non-magnetic substrate 1 and the hard-magnetic layer 10.

The perpendicular magnetic recording medium having the aforementioned layer configuration is produced through the following procedure. Firstly, the hard-magnetic layer 10 is formed on the non-magnetic substrate 1, and the soft-magnetic under layer 2 is formed thereon through, for example, sputtering. Subsequently, the surface of the soft-magnetic under layer 2 is oxidized in accordance with needs. On the under layer, the alignment control layer 3, an intermediate film 4, and the perpendicular magnetic layer 5 are formed through, for example sputtering. Subsequently, a protective layer 6 is formed through CVD, the ion-beam method, sputtering, or a similar method. Finally, a lubricating layer 7 is formed through dipping, spin-coating, or a similar method.

The hard-magnetic layer may be formed through a method for fabricating a conventional longitudinal anisotropic medium. For example, a stacked structure of a glass substrate/NiAl alloy layer/CrMo alloy layer/CoCr alloy layer/CoCrPtB alloy layer may be produced. To the magnetic recording medium which has been equipped with a protective layer, a magnetic field is applied in the radial direction of the recording medium, to thereby impart radial magnetization to the hard-magnetic layer. The intensity of the magnetic field to be applied is such that the hard-magnetic layer sufficiently attains magnetic saturation. For example, the intensity is preferably 790,000 A/m (10,000 [Oe]) or more.

### EXAMPLES

The effects of the present invention will next be described by way of Examples, which should not be construed as limiting the invention thereto.

### Example 1

A glass substrate (product of OHARA INC., outer diameter: 2.5 inches) was washed and then placed in a film-forming chamber of a DC magnetron sputtering apparatus (C-3010, product of ANELVA). The chamber was evacuated to 1×10⁻⁵ Pa. By use of a target formed of 89Co4Zr7Nb (Co: 89 at. %, Zr: 4 at. %, Nb: 7 at. %), a soft-magnetic under layer 2 (thickness: 100 nm) was formed on the glass substrate through sputtering at a substrate temperature of 100° C. or lower.

Subsequently, an alignment control layer 3 (thickness: 6 nm) was formed on the soft-magnetic under layer by use of a target formed of Pd. On the thus-formed Pd layer were sequentially formed an intermediate layer 4 (thickness: 20 nm) by use of a target formed of Ru, a first perpendicular magnetic layer 5 (thickness: 10 nm) by use of a target formed of CoCrPt—SiO₂ (SiO₂ (8 mol) dispersed in a CoCrPt alloy (Co: 74 at. %, Cr: 10 at. %, Pt: 16 at. %)), a second perpendicular magnetic layer 6 (thickness: 5 nm) by use of a target formed of CoCr (Co: 73 at. %, Cr: 27 at. %), and a third perpendicular magnetic layer 7 (thickness: 4 nm) by use of a sputtering target formed of CoCrPtB (Cr: 21 at. %, Pt: 16 at. %, B: 1 at. %). In the above sputtering steps, Ar was used as a sputtering gas for film formation. The first perpendicular magnetic layer was formed at a gas pressure of 10 Pa, and the other layers were formed at a gas pressure of 0.6 Pa. Subsequently, a protective layer 6 (thickness: 5 nm) was formed thereon through CVD, and a lubricating layer 7 made of perfluoropolyether was formed thereon through the dipping method, to thereby produce a perpendicular magnetic recording medium.

### Example 2

The procedure of Example 1 was repeated, except that a third perpendicular magnetic layer (thickness: 5 nm) was formed by use of a sputtering target formed of CoCrPtB (Cr: 21 at. %, Pt: 16 at. %, B: 1 at. %) after formation of the first perpendicular magnetic layer 5 and the second perpendicular magnetic layer 6, to thereby produce a magnetic recording medium.

### Examples 3 and 4

The procedure of Example 2 was repeated, except that the thickness of the first perpendicular magnetic layer and that of the second perpendicular magnetic layer were changed, to thereby produce magnetic recording media of Examples 3 and 4.

### Comparative Example 1

The procedure of Example 1 was repeated, except that no second perpendicular magnetic layer was formed, to thereby produce a magnetic recording medium of Comparative Example 1.

### Comparative Example 2

The procedure of Example 2 was repeated, except that no second perpendicular magnetic layer was formed, to thereby produce a magnetic recording medium of Comparative Example 2.

### Comparative Examples 3 and 4

Magnetic recording media of Comparative Examples 3 and 4 were produced without forming second perpendicular magnetic layer. Other conditions were the same as employed in Examples 3 and 4.

The magnetic recording media produced in Examples 1 to 4 and Comparative Examples 1 to 4 were evaluated in terms of magnetic characteristics by means of a vibrating sample magnetometer.

Recording and reproducing characteristics were investigated by means of a read-write analyzer RWA 1632 (product of GUZIK) and a spin stand S1701MP. Read-write characteristics were evaluated by means of a complex thin-film magnetic recording head having a giant magnetoresistance (GMR) element serving as a readout portion. In the measurement, recording was performed at a linear recording density of 500 kFCI.

Table 1 shows the conditions employed in Examples 1 to 4 and Comparative Examples 1 to 4 and results.

TABLE 1

| | | | | | Comp. | Comp. | Comp. | Comp. |
|---|---|---|---|---|---|---|---|---|
| | Ex. 1 | Ex. 2 | Ex. 3 | Ex. 4 | Ex. 1 | Ex. 2 | Ex. 3 | Ex. 4 |
| First | 10 nm | 10 nm | 10 nm | 10 nm | 10 nm | 10 nm | 10 nm | 10 nm |
| perpendicular | | | | | | | | |
| magnetic layer | | | | | | | | |
| CoCrPt—SiO₂ | | | | | | | | |
| Second | 5 nm | 5 nm | 6 nm | 7 nm | none | none | none | none |
| perpendicular | | | | | | | | |
| magnetic layer | | | | | | | | |
| CoCr | | | | | | | | |
| Third | 4 nm | 5 nm | 6 nm | 7 nm | none | 5 nm | 6 nm | 7 nm |
| perpendicular | | | | | | | | |
| magnetic layer | | | | | | | | |
| CoCrPtB | | | | | | | | |
| Hc [Oe] | 3912 | 3937 | 4211 | 4497 | 5112 | 4539 | 4436 | 4332 |
| -Hn [Oe] | 2001 | 2066 | 2057 | 2220 | 1678 | 2130 | 2144 | 2111 |
| LF [mV] | 3.102 | 3.012 | 3.141 | 3.228 | 2.344 | 2.717 | 2.354 | 2.802 |
| SNR [dB] | 27.2 | 27.2 | 28.0 | 27.2 | 26.0 | 26.7 | 26.4 | 26.0 |
| OW [dB] | 47.6 | 48.7 | 47.0 | 45.2 | 29.0 | 27.0 | 20.8 | 28.0 |

As is clear from Table 1, the recording and reproducing characteristics, particularly SNR and OW, depend considerably on the presence of the second perpendicular magnetic layer. As used herein, “SNR” refers the output/media noise ratio obtained during recording and reproducing performed under predetermined conditions. The higher the SNR value, the higher the performance of the recording medium. SNR is generally represented by the unit of dB. “OW” refers to the ratio (dB) of signal output of initial frequency component to that of overwrite frequency component, wherein the reproduction signal is obtained after recording information at a certain frequency over the recorded information at a different frequency. The higher the OW value, the higher the performance of the recording medium. In the case of perpendicular magnetic recording media, when the initial signal is higher frequency and the overwrite signal is lower frequency, severe recording conditions are realized. The above measurement is performed under the above conditions.

### Examples 5 to 8

In Examples 5 to 8, a perpendicular magnetic layer 1 of each sample was produced by use of a target formed of CoCrPtCu—SiO₂ (SiO₂ (8 mol) dispersed in a CoCrPt alloy (Co: 70 at. %, Cr: 10 at. %, Pt: 16 at. %, Cu: 4 at. %)). Other conditions were the same as employed in Examples 1 to 4. The thus-produced recording media were evaluated in a manner similar to that employed in Examples 1 to 4. The results are shown in Table 2.

TABLE 2

| | Ex. 5 | Ex. 6 | Ex. 7 | Ex. 8 |
|---|---|---|---|---|
| First perpendicular | 10 nm | 10 nm | 10 nm | 10 nm |
| magnetic layer | | | | |
| CoCrPtCu—SiO₂ | | | | |
| Second perpendicular | 5 nm | 5 nm | 6 nm | 7 nm |
| magnetic layer | | | | |
| CoCr | | | | |
| Third perpendicular | 4 nm | 5 nm | 6 nm | 7 nm |
| magnetic layer | | | | |
| CoCrPtB | | | | |
| Hc [Oe] | 4032 | 4002 | 4189 | 4466 |
| -Hn [Oe] | 1997 | 2032 | 2044 | 2186 |
| LF [mV] | 3.002 | 2.999 | 3.044 | 3.134 |
| SNR [dB] | 27.5 | 27.1 | 28.2 | 27.5 |
| OW [dB] | 48.0 | 48.9 | 48.0 | 46.8 |

As is clear from Table 2, even when Cu was added the first perpendicular magnetic layer, effects of insertion of the second perpendicular magnetic layer are similarly attained.

In the production of samples of Examples 9 to 12, a hard-magnetic layer (CoCrPtB/CrMo) was formed under a soft-magnetic layer by use of a sputtering target formed of CoW (Co: 50 at. %, W: 50 at. %), CrMo (Co: 80 at. %, Mo 20 at. %), and CoCrPtB (Co: 64 at. %, Cr 21 at. %, Pt: 16 at. %, B: 1 at. %). Other conditions were the same as employed in Examples 1 to 4. In the above samples, the hard-magnetic layer was formed of CoW (20 nm), CrMo (20 nm), and CoCrPtB (30 nm) on the substrate in this order.

These samples were evaluated in a manner similar to that of Examples 1 to 4. The results are shown in Table 3.

TABLE 3

| | Ex. 9 | Ex. 10 | Ex. 11 | Ex. 12 |
|---|---|---|---|---|
| Hard-magnetic | CoCrPtB(30 nm)/ | CoCrPtB(30 nm)/ | CoCrPtB(30 nm)/ | CoCrPtB(30 nm)/ |
| layer | CrMo(20 nm)/ | CrMo(20 nm)/ | CrMo(20 nm)/ | CrMo(20 nm)/ |
| | CoW(20 nm) | CoW(20 nm) | CoW(20 nm) | CoW(20 nm) |
| First | 10 nm | 10 nm | 10 nm | 10 nm |
| perpendicular | | | | |
| magnetic layer | | | | |
| CoCrPtCu—SiO₂ | | | | |
| Second | 5 nm | 5 nm | 6 nm | 7 nm |
| perpendicular | | | | |
| magnetic layer | | | | |
| CoCr | | | | |
| Third | 4 nm | 5 nm | 6 nm | 7 nm |
| perpendicular | | | | |
| magnetic layer | | | | |
| CoCrPtB | | | | |
| Hc [Oe] | 4133 | 4111 | 4221 | 4478 |
| -Hn [Oe] | 2045 | 2099 | 2122 | 2155 |
| LF [mV] | 3.100 | 3.043 | 3.054 | 3.045 |
| SNR [dB] | 27.4 | 27.0 | 28.4 | 27.2 |
| OW [dB] | 47.9 | 48.0 | 46.9 | 47.1 |

As is clear from Table 3, formation of a hard-magnetic layer under the soft-magnetic layer does not considerably affect the effects of the present invention.

### Examples 13 to 16

The procedure of Example 2 was performed, except that the Cr content of the perpendicular magnetic layer 2 was changed to 15 at. %, 20 at. %, 37 at. %, and 40 at. %, to thereby produce samples of Examples 13 to 16, respectively. These samples were evaluated in a manner similar to that of Example 1 and Comparative Example 1. The results are shown in Table 4.

TABLE 4

| | | | | | | Comp. |
|---|---|---|---|---|---|---|
| | Ex. 13 | Ex. 14 | Ex. 1 | Ex. 15 | Ex. 16 | Ex. 1 |
| First | 10 nm | 10 nm | 10 nm | 10 nm | 10 nm | 10 nm |
| perpendicular | | | | | | |
| magnetic layer | | | | | | |
| CoCrPt—SiO₂ | | | | | | |
| Second | Cr 15 | Cr 20 | Cr 27 | Cr 37 | Cr 40 | none |
| perpendicular | at. % | at. % | at. % | at. % | at. % | |
| magnetic layer | 5 nm | 5 nm | 5 nm | 5 nm | 5 nm | |
| CoCr | | | | | | |
| Hc [Oe] | 4397 | 4427 | 4545 | 4554 | 4600 | 5112 |
| -Hn [Oe] | 1998 | 2054 | 2176 | 2298 | 2302 | 1678 |
| LF [mV] | 3.322 | 3.111 | 3.102 | 3.011 | 3.132 | 2.344 |
| SNR [dB] | 25.3 | 26.2 | 27.2 | 26.0 | 25.5 | 26.0 |
| OW [dB] | 41.2 | 43.3 | 47.6 | 40.3 | 40.4 | 29.0 |

As is clear from Table 4, recording and reproducing characteristics are enhanced when the second perpendicular magnetic layer has a Cr content of 20 at. % to 37 at. %.

### Examples 17 to 20

The procedure of Example 2 was repeated, except that the sputtering gas pressure during formation of the first perpendicular magnetic layer was changed, to thereby produce samples of Examples 17 to 20. These samples were evaluated in a manner similar to that of Example 1. Sputtering gas pressure employed during formation of the first perpendicular magnetic layer in the Examples and evaluation results are shown in Table 5.

TABLE 5

| | | | | | | | | | | | Comp. | |
|---|---|---|---|---|---|---|---|---|---|---|---|---|
| | Ex. 17 | | Ex. 18 | | Ex. 1 | | Ex. 19 | | Ex. 20 | | Ex. 1 | |
| First | 10 | nm | 10 | nm | 10 | nm | 10 | nm | 10 | nm | 10 | nm |
| perpendicular | 3 | Pa | 5 | Pa | 10 | Pa | 20 | Pa | 25 | Pa | 10 | Pa |
| magnetic layer | | | | | | | | | | | | |
| CoCrPt—SiO₂ | | | | | | | | | | | | |
| Second | 5 | nm | 5 | nm | 5 | nm | 5 | nm | 5 | nm | none | |
| perpendicular | | | | | | | | | | | | |
| magnetic layer | | | | | | | | | | | | |
| CoCr | | | | | | | | | | | | |

| | | | | | | |
|---|---|---|---|---|---|---|
| Hc [Oe] | 4123 | 4346 | 4545 | 4555 | 4478 | 5112 |
| -Hn [Oe] | 1954 | 2034 | 2176 | 2187 | 2170 | 1678 |
| LF [mV] | 3.002 | 3.043 | 3.102 | 3.103 | 3.100 | 2.344 |
| SNR [dB] | 24.6 | 26.1 | 27.2 | 27.2 | 24.6 | 26.0 |
| OW [dB] | 46.3 | 46.3 | 47.6 | 47.0 | 44.0 | 29.0 |

As is clear from Table 5, the sputtering gas pressure during formation of the first perpendicular magnetic layer is appropriately 5 Pa to 20 Pa.

### Examples 21 to 24

The procedure of Example 2 was repeated, except that the sputtering gas pressure during formation of the second perpendicular magnetic layer was changed, to thereby produce samples of Examples 21 to 24. These samples were evaluated in a manner similar to that of Example 1. Sputtering gas pressure employed during formation of the second perpendicular magnetic layer in the Examples and evaluation results are shown in Table 6.

TABLE 6

| | | | | | | | | | | | Comp. |
|---|---|---|---|---|---|---|---|---|---|---|---|
| | Ex. 21 | | Ex. 22 | | Ex. 1 | | Ex. 23 | | Ex. 24 | | Ex. 1 |
| First | 10 | nm | 10 | nm | 10 | nm | 10 | nm | 10 | nm | 10 nm |
| perpendicular | | | | | | | | | | | |
| magnetic layer | | | | | | | | | | | |
| CoCrPt—SiO₂ | | | | | | | | | | | |
| Second | 5 | nm | 5 | nm | 5 | nm | 5 | nm | 5 | nm | none |
| perpendicular | 0.1 | Pa | 0.3 | Pa | 0.6 | Pa | 1.5 | Pa | 5 | Pa | |
| magnetic layer | | | | | | | | | | | |
| CoCr | | | | | | | | | | | |

| | | | | | | |
|---|---|---|---|---|---|---|
| Hc [Oe] | 4343 | 4409 | 4545 | 4599 | 4032 | 5112 |
| -Hn [Oe] | 2000 | 2056 | 2176 | 2199 | 1977 | 1678 |
| LF [mV] | 2.978 | 3.087 | 3.102 | 3.243 | 3.331 | 2.344 |
| SNR [dB] | 25.9 | 26.8 | 27.2 | 26.4 | 24.5 | 26.0 |
| OW [dB] | 48.0 | 48.0 | 47.6 | 47.0 | 48.7 | 29.0 |

As is clear from Table 6, the sputtering gas pressure during formation of the second perpendicular magnetic layer is appropriately 0.1 Pa to 1.5 Pa.

### Examples 25 and 26

The procedure of Example 2 was repeated, except that the Cr content of the first perpendicular magnetic layer was changed to 4 at. % and 30 at. %, to thereby produce samples of Examples 25 and 26. Magnetic characteristics and read-write characteristics of the samples of Examples 2, 25, and 26 were compared. Table 7 shows the results.

TABLE 7

| | Ex. 2 | Ex. 25 | Ex. 26 |
|---|---|---|---|
| First perpendicular | 10 nm | 10 nm | 10 nm |
| magnetic layer | Cr 10 at. % | Cr 4 at. % | Cr 29 at. % |
| CoCrPt—SiO | | | |
| Second perpendicular | 5 nm | 5 nm | 5 nm |
| magnetic layer | | | |
| CoCr | | | |
| Third perpendicular | 5 nm | 5 nm | 5 nm |
| magnetic layer | | | |
| CoCrPtB | | | |
| Hc [Oe] | 3937 | 2454 | 3021 |
| -Hn [Oe] | 2066 | 1201 | 1332 |
| LF [mV] | 3.012 | 2.648 | 2.989 |
| SNR [dB] | 27.2 | 23.3 | 24.1 |
| OW [dB] | 48.7 | 50.3 | 51.3 |

As is clear from Table 7, static magnetic characteristics and read-write characteristics are impaired when the first perpendicular magnetic layer has a Cr content of 4 at. % to 29 at. %.

### Examples 27 and 28

The procedure of Example 2 was repeated, except that the Cr content of the third perpendicular magnetic layer was changed to 17 at. % and 30 at. %, to thereby produce samples of Examples 27 and 28. Magnetic characteristics and read-write characteristics of the samples of Examples 2, 27, and 28 were compared. Table 8 shows the results.

TABLE 8

| | Ex. 2 | Ex. 27 | Ex. 28 |
|---|---|---|---|
| First perpendicular | 10 nm | 10 nm | 10 nm |
| magnetic layer | | | |
| CoCrPt—SiO | | | |
| Second perpendicular | 5 nm | 5 nm | 5 nm |
| magnetic layer | | | |
| CoCr | | | |
| Third perpendicular | 5 nm | 5 nm | 5 nm |
| magnetic layer | Cr 21 at. % | Cr 17 at. % | Cr 29 at. % |
| CoCrPtB | | | |
| Hc [Oe] | 3937 | 4001 | 4109 |
| -Hn [Oe] | 2066 | 2111 | 2211 |
| LF [mV] | 3.012 | 3.110 | 3.132 |
| SNR [dB] | 27.2 | 24.4 | 25.9 |
| OW [dB] | 48.7 | 47.7 | 47.6 |

As is clear from Table 8, read-write characteristics, among other properties, are impaired when the third perpendicular magnetic layer has a Cr content of 17 at. % to 29 at. %.

### INDUSTRIAL APPLICABILITY

The present invention provides a perpendicular magnetic recording medium of the present invention including at least

a non-magnetic substrate, and on the substrate, an alignment control layer for aligning crystal orientation in a layer provided directly thereon, a perpendicular magnetic layer in which easy-magnetization axes are oriented in a direction virtually normal to a substrate, and a protective layer, characterized in that the perpendicular magnetic layer contains Co as a predominant component and is formed of at least three layers of a first perpendicular magnetic layer formed predominantly from a material containing at least Cr, Pt, and a metal oxide or a semiconductor oxide, a second perpendicular magnetic layer formed predominantly from a CoCr alloy, and a third perpendicular magnetic layer formed predominantly from a CoCrPtB-based alloy, the three layers being stacked on the substrate in this order.

Through employment of the magnetic recording medium, magnetic coupling between the first perpendicular magnetic layer and the third perpendicular magnetic layer is weakened by the second perpendicular magnetic layer, while excellent thermal fluctuation resistance is maintained. Thus, media noise can be reduced, while high ferromagnetic property is maintained.

Therefore, a perpendicular magnetic recording medium which exhibits enhanced recording and reproducing characteristics and which can record and reproduce information at high density can be produced.

1. A perpendicular magnetic recording medium comprising:
a non-magnetic substrate;
an alignment control layer on the substrate, for aligning crystal orientation in a layer provided directly thereon;
a perpendicular magnetic layer in which easy-magnetization axes are oriented in a direction virtually normal to a substrate; and
a protective layer,
wherein the perpendicular magnetic layer contains Co as a predominant component and comprises
a first perpendicular magnetic layer formed predominantly from a material containing at least Cr, Pt, and a metal oxide or a semiconductor oxide,
a second perpendicular magnetic layer formed predominantly from a CoCr alloy, and
a third perpendicular magnetic layer formed predominantly from a CoCrPtB-based alloy, the three layers being stacked on the substrate in this order.

2. A perpendicular magnetic recording medium according to claim 1, wherein the first perpendicular magnetic layer is a granular layer, and each of the second perpendicular magnetic layer and the third perpendicular magnetic layer is a non-granular layer.

3. A perpendicular magnetic recording medium according to claim 1, wherein the CoCr alloy forming the second perpendicular magnetic layer has a Cr content of 20 at. % to 37 at. %.

4. A perpendicular magnetic recording medium according to claim 1, wherein the first perpendicular magnetic layer is formed from a material having a Cr content of 5 at. % to 28 at. % and a Pt content of 10 at. % to 20 at. %.

5. A perpendicular magnetic recording medium according to claim 1, wherein the third perpendicular magnetic layer is formed from a material having a Cr content of 18 at. % to 28 at. % and a Pt content of 10 at. % to 20 at. %.

6. A perpendicular magnetic recording medium according to claim 1, wherein the first perpendicular magnetic layer is formed from a material containing at least one element selected from among B, Ta, and Cu in a total amount of 8 at. % or less.

7. A perpendicular magnetic recording medium according to claim 1, wherein the second perpendicular magnetic layer contains at least one element selected from among Ta, Pt, B, and Cu and a total amount of Cr and these elements is 20 at. % to 37 at. %.

8. A perpendicular magnetic recording medium according to claim 1, wherein the third perpendicular magnetic layer contains at least one element selected from among B, Nd, Ta, and Cu, and the total amount of Cr, Pt, and these elements is 40 at. % or less.

9. A perpendicular magnetic recording medium according to claim 1, further comprising a soft-magnetic under layer, formed from a soft-magnetic material, between the non-magnetic substrate and the alignment control layer.

10. A perpendicular magnetic recording medium according to claim 9, further comprising a hard-magnetic layer which magnetic anisotropy oriented in substantially a longitudinal direction, between the non-magnetic substrate and the soft-magnetic under layer.

11. A perpendicular magnetic recording medium according to claim 10, wherein the hard-magnetic layer comprises a CoSm alloy or a CoCrPtX (X: one or more species selected from among Pt, Ta, Zr, Nb, Cu, Re, Ni, Mn, Ge, Si, O, N and B) and has a coercive force of 500 [Oe] (39.5 kA/m) or more and a magnetization direction aligned with the radial direction of the substrate.

12. A perpendicular magnetic recording medium according to claim 1, wherein the first perpendicular magnetic layer is formed in a film formation step employing a sputtering gas pressure of 5 to 20 Pa.

13. A perpendicular magnetic recording medium according to claim 1, wherein the second perpendicular magnetic layer and the third perpendicular magnetic layer are formed in a film formation step employing a sputtering gas pressure of 0.1 to 1.5 Pa.

14. A magnetic recording and reproducing apparatus comprising a perpendicular magnetic recording medium, and a magnetic head for recording information to and reproducing information from the perpendicular magnetic recording medium, wherein the perpendicular magnetic recording medium is a perpendicular magnetic recording medium according to claim 1.

15. A method for producing a perpendicular magnetic recording medium comprising:
a non-magnetic substrate;
an alignment control layer on the substrate, for aligning crystal orientation in a layer provided directly thereon;
a perpendicular magnetic layer in which an easy-magnetization easy is oriented in a direction virtually normal to a substrate; and
a protective layer,
wherein the perpendicular magnetic layer contains Co as a predominant component and comprises
a first perpendicular magnetic layer formed predominantly from a material containing at least Cr, Pt, and a metal oxide or a semiconductor oxide,
a second perpendicular magnetic layer formed predominantly from a CoCr alloy, and
a third perpendicular magnetic layer formed predominantly from a CoCrPtB-based alloy, the three layers being stacked on the substrate in this order,
wherein,
the first perpendicular magnetic layer is formed in a film formation step employing a sputtering gas pressure of 5 to 20 Pa.

16. A method for producing a perpendicular magnetic recording medium according to claim 15, wherein the second perpendicular magnetic layer and the third perpendicular magnetic layer are formed in a film formation step employing a sputtering gas pressure of 0.1 to 1.5 Pa.
